(19) United States
(12) Patent Application Publication
(10) Pub. No.: US 2026/0291461 A1
(43) Pub. Date: Sep. 24, 2026

(54) IMPEDANCE ADJUSTMENT CIRCUIT

(71) Applicant: INDUSTRIAL COOPERATION FOUNDATION JEONBUK NATIONAL UNIVERSITY, Jeollabuk-do (KR)

(72) Inventors: Cheon Yong LIM, Jeollabuk-do (KR); Yong Sug SUH, Jeollabuk-do (KR); Hong Min KIM, Gwangju (KR)

(21) Appl. No.: 18/874,276

(22) PCT Filed: Apr. 10, 2023
(86) PCT No.: PCT/KR2023/004779

§ 371 Date: Dec. 12, 2024

(30) Foreign Application Priority Data
Jun. 13, 2022 (KR) 10-2022-0071786

(51) Int. Cl. H03H 7/40; H01J 37/32

(52) U.S. Cl. CPC H03H 7/40; H01J 37/32183; H01J 2237/334

(57) ABSTRACT

An impedance adjustment circuit for adjusting an impedance by adjusting an equivalent capacitance according to an embodiment of the present invention comprises: a capacitor; a unit leg configured to change the equivalent capacitance according to a connection with the capacitor; and a control unit configured to control the unit leg to change the equivalent capacitance, wherein an inductor and a compensation voltage source are included so as to be connected in parallel with the unit leg.

### TECHNICAL FIELD

The present disclosure generally relates to an impedance adjustment circuit.

### BACKGROUND ART

Semiconductor manufacturing processes include various unit processes, and representative examples of these unit processes include an etching process and a deposition process. Today's etching and deposition processes are representative examples of processes that utilize plasma.

In these processes, plasma equipment is used, and the impedance of an input side is matched with the impedance of a load side to ensure maximum power transmission to the load side.

Since a plasma load is a load that continuously changes in value depending on the type and amount of gas used in a chamber and whether plasma is generated, an impedance matching circuit is essential to continuously match the impedance with that of the input side to cope with these characteristics.

### DISCLOSURE

### Technical Problem

In conventional impedance matching circuits, a vacuum variable capacitor that mechanically adjusts capacitance has been used. However, the vacuum variable capacitor has an issue of slower adjustment time because the capacitance is mechanically varied. The time required to mechanically change the capacitance accounts for 30% of the total etching process time.

The present embodiment aims to overcome the challenges of the related art. In other words, one of the objectives of the present embodiment is to provide an impedance adjustment circuit capable of rapidly changing the capacitance electrically.

### Technical Solution

One aspect of the present invention provides an impedance adjustment circuit configured to adjust an impedance by adjusting an equivalent capacitance, including a capacitor, a unit leg configured to change the equivalent capacitance according to a connection with the capacitor, a control unit configured to control the leg to change the equivalent capacitance, and an inductor and a compensation voltage source connected in parallel with the leg.

Another aspect of the present invention provides an impedance adjustment circuit configured to adjust an impedance by adjusting an equivalent capacitance, including a capacitor, a unit leg configured to change the equivalent capacitance according to a connection with the capacitor, and a control unit configured to control the leg to change the equivalent capacitance, wherein the unit leg includes a diode that has an anode connected to a radio frequency (RF) rail and conducts to change the equivalent capacitance when the control unit controls the leg to increase the equivalent capacitance.

According to one aspect of the present embodiment, the unit leg may include an adjustment capacitor that has one electrode connected to a reference voltage rail and is equivalently connected to the capacitor to adjust the equivalent capacitance, a leg voltage source, two switches connected in series with the leg voltage source, a first inductor having one electrode connected to a node to which the two switches are connected and the other electrode connected to the other electrode of the adjustment capacitor, and a diode connected to an RF rail and having an anode to which an RF voltage is provided and a cathode connected to the other electrode of the first inductor.

According to one aspect of the present embodiment, the capacitor may have one electrode connected to the RF rail and the other electrode connected to the reference voltage rail.

According to one aspect of the present embodiment, a voltage provided by the leg voltage source may be greater in magnitude than the RF voltage provided to the RF rail.

According to one aspect of the present embodiment, the compensation voltage source may compensate for a voltage drop when the switch is turned on and a forward voltage drop of the diode.

According to one aspect of the present embodiment, the adjustment capacitor may be connected in parallel with the capacitor through the diode, so that the equivalent capacitance is adjusted.

According to one aspect of the present embodiment, the two switches may include a first switch connected to the reference voltage rail and a second switch connected to the leg voltage source, and when the second switch is turned off and the first switch is turned on, the adjustment capacitor and the capacitor may be equivalently connected in parallel, so that the equivalent capacitance is adjusted.

According to one aspect of the present embodiment, when the first switch is turned off and the second switch is turned on, the connection between the adjustment capacitor and the capacitor may be equivalently cut off.

According to one aspect of the present embodiment, the unit leg may be provided as a plurality of unit legs connected in parallel.

According to one aspect of the present embodiment, the adjustment capacitors included in the plurality of unit legs may have different capacitances.

According to one aspect of the present embodiment, the control unit may control the adjustment capacitor included in one of the plurality of unit legs to be equivalently connected to the capacitor.

According to one aspect of the present embodiment, the diode may be a P-type-intrinsic-N-type (PIN) diode.

### Advantageous Effects

According to the present embodiment, there is an advantage in that capacitance can be rapidly changed through a control signal, thereby improving semiconductor productivity.

### DESCRIPTION OF DRAWINGS

FIG. 1 is a diagram illustrating one embodiment of an impedance adjustment circuit according to the present embodiment.

FIG. 2 is a diagram for describing operation of the present embodiment during a preparation phase.

FIG. 3 is a diagram for describing operation of the present embodiment during an impedance adjustment phase.

FIG. 4 is a diagram illustrating an impedance adjustment circuit formed by a plurality of unit legs.

### MODES OF THE INVENTION

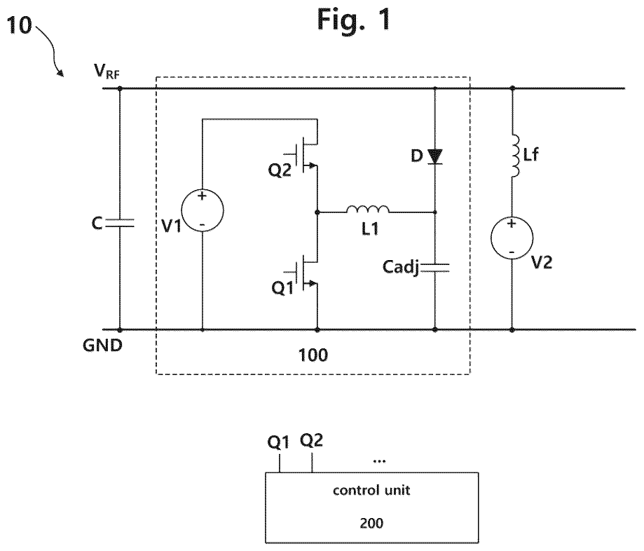

Hereinafter, the present embodiment will be described with reference to the accompanying drawings. FIG. 1 is a diagram illustrating one embodiment of an impedance adjustment circuit according to the present embodiment. Referring to FIG. 1, an impedance adjustment circuit 10 is an impedance adjustment circuit that adjusts impedance by adjusting equivalent capacitance and includes a capacitor C, a unit leg 100 that changes the equivalent capacitance depending on a connection with the capacitor C, a control unit 200 that controls the leg to change the equivalent capacitance, and an inductor Lf and a compensation voltage source V2 connected in parallel with the leg 100. As will be described below, a plurality of legs 100 may be connected in parallel.

As illustrated in the embodiment, a voltage provided by a leg voltage source V1 is greater in magnitude than a radio frequency (RF) voltage V_{RF} supplied through an RF rail. Thus, when the RF voltage V_{RF} is applied to an anode of a diode D and the voltage provided by the leg voltage source V1 is applied to a cathode of the diode D, the diode may be blocked.

In the illustrated embodiment, the diode D may be a P-type-intrinsic-N-type (PIN) diode. The PIN diode is a diode formed by interposing an intrinsic semiconductor between a P-type doped semiconductor and an N-type doped semiconductor. The PIN diode has a lower junction capacitance compared to a junction capacitance of a PN diode in which P-type and N-type semiconductors form a junction.

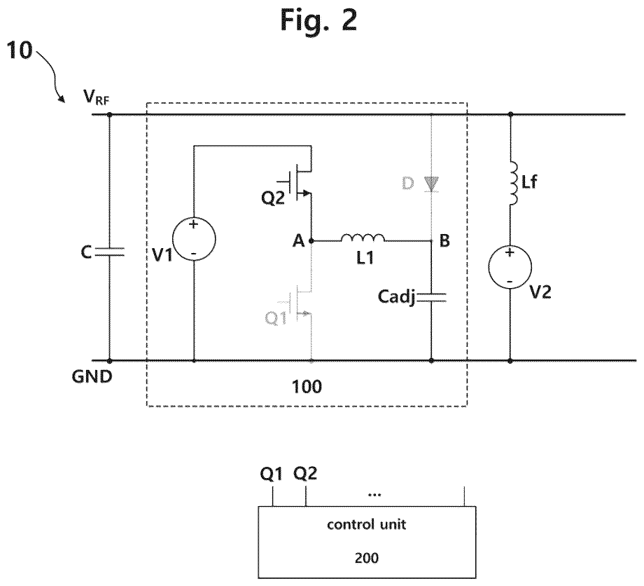

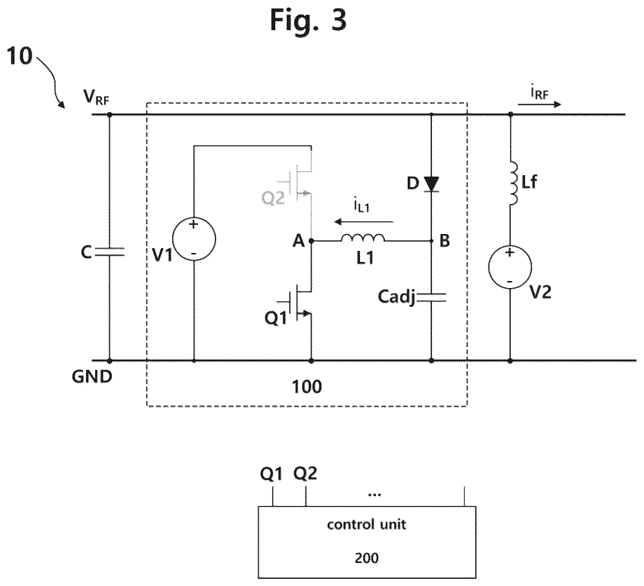

FIGS. 2 and 3 are diagrams for describing operation of the impedance adjustment circuit 10 according to the present embodiment during a preparation phase and an impedance adjustment phase. FIG. 2 is a diagram for describing the operation of the present embodiment during the preparation phase. Referring to FIG. 2, the control unit 200 provides control signals to control switches Q1 and Q2. In the preparation phase illustrated in FIG. 2, the control unit 200 provides control signals to turn off the switch Q1 and turn on the switch Q2. In the illustrated embodiment, the switches Q1 and Q2 may be n-channel metal-oxide-semiconductor (NMOS) transistors. In another embodiment not illustrated, the switches Q1 and Q2 may be implemented as semiconductor switches, such as p-channel metal-oxide-semiconductor (PMOS) transistors.

The control unit 200 may provide a control signal in a logic low state to a gate electrode of the switch Q1 and a control signal in a logic high state to a gate electrode of the switch Q2, thereby turning off the switch Q1 and turning on the switch Q2.

When the switch Q2 is turned on and passes through a transient state to reach a steady state, an inductor L1 is treated as being equivalent to a conducting wire due to voltage-second balance. The voltage-second balance of the inductor means that in a steady state, an average voltage across the inductor over one switching cycle must be zero. Accordingly, in the steady state, there is no voltage difference between nodes A and B across the inductor L1, and as a result, the inductor L1 is equivalent to a conducting wire.

Since the cathode of the diode D is connected to the node B, the voltage provided by the leg voltage source V1 is provided to the cathode, and the RF voltage V_{RF} is provided to the anode of the diode D from the RF rail. V1, the voltage provided by the leg voltage source V1, is greater than V_{RF}, the voltage provided by the RF rail. Accordingly, a reverse voltage is applied to the diode D, which causes the diode D to be blocked.

As described above, a parasitic capacitor formed in the diode D has a low capacitance value, thereby forming a high impedance. Accordingly, an adjustment capacitor Cadj, as seen from the capacitor C through the RF rail, is electrically equivalent to being blocked due to the impedance of the parasitic capacitor in the diode D.

FIG. 3 is a diagram for describing the operation of the present embodiment during the impedance adjustment phase. Referring to FIG. 3, in the impedance adjustment phase, the control unit 200 provides control signals to turn off the switch Q2 and turn on the switch Q1. An inductor current I_{L1}, which is a direct current and greater than the maximum value of an RF current I_{RF}, flows through the inductor L1, and the RF current IRF and the current I_{L1} combine and flow through the diode D. Thus, a current greater than zero always flows through the diode D, thereby causing the diode D to conduct.

As the diode D conducts, the capacitor C and the adjustment capacitor Cadj are connected in parallel. Thus, an equivalent capacitance Ceq is formed as the sum of the capacitances of the two capacitors, i.e., C+Cadj, and may be formed to achieve the desired capacitance, thereby performing impedance adjustment.

In the impedance adjustment phase, in a path in which the diode D, the inductor, and the switch Q1 are connected, a forward voltage drop is formed across the diode D1 when the diode D1 conducts, and a voltage drop is formed due to a conduction resistance when a current flows through the switch Q1.

In order to compensate for the voltage drops formed in the diode D1 and the switch Q1, a compensation voltage source V2 provides a compensation voltage. A magnitude of the compensation voltage may correspond to the sum of the forward voltage drop of the diode D1 and the voltage drop caused by the conduction resistance of the switch Q1. In addition, the compensation voltage source V2 is connected in series with an inductor Lf. In the impedance adjustment phase, when the leg 100 is in a steady state, the inductor Lf is equivalent to a conducting wire due to the voltage-second balance.

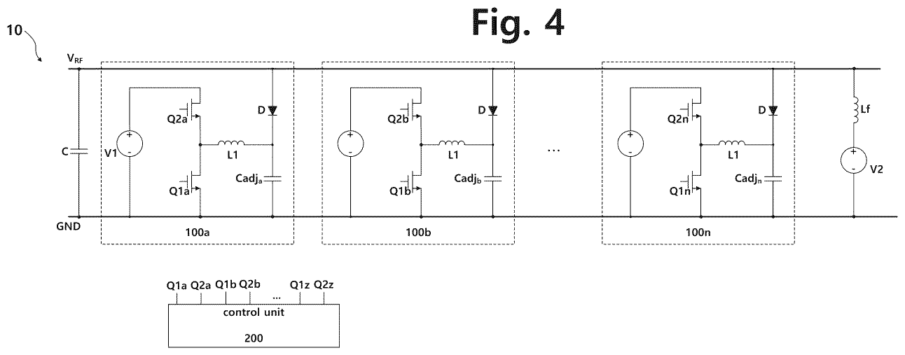

FIG. 4 is a diagram illustrating an impedance adjustment circuit formed by a plurality of unit legs 100. Referring to FIG. 4, the illustrated impedance adjustment circuit includes a plurality of unit legs 100a, 100b, . . . , and 100n. Capacitances of adjustment capacitors Cadjₐ, Cadj_{b}, . . . , and Cadjₙ included in the unit legs 100a, 100b, . . . , and 100n, respectively, may be different from one another.

Accordingly, the control unit 200 may select the unit leg that includes a capacitance matched to an impedance of a load (not shown) so that maximum power can be transmitted according to the impedance of the load and provide control signals to activate the selected leg and connect the capacitor C and the corresponding adjustment capacitor in parallel, thereby performing impedance matching.

According to the related art, an independent power source is formed in each unit capacitance adjustment part. However, in the related art, the independent power source utilizes an isolation transformer to reduce the impact of noise, but when the isolation transformer is included in each unit capacitance adjustment part, the number of components increases, which results in issues such as increased volume and higher circuit manufacturing cost.

However, according to the present embodiment, by using a single inductor and compensation voltage source to compensate for the voltage drop formed in the selected unit leg, it is possible to reduce the product volume compared to the related art and decrease the number of components in the circuit, thereby providing an economic advantage.

This application is the result of the Sector Coupling Energy Industry Advancement Manpower Training Program (Task No.: 20224000000440) supported by a grant from the Ministry of Trade, Industry, and Energy of the Republic of Korea.

Although the present invention has been described with reference to the embodiments illustrated in the drawings to aid in understanding of the present invention, these are for illustrative purposes only, and it should be understood that various alterations and other equivalent embodiments may be made by those skilled in the art. Therefore, the true technical scope of the present invention should be determined only by the appended claims.

1. An impedance adjustment circuit configured to adjust an impedance by adjusting an equivalent capacitance, the impedance adjustment circuit comprising:
a capacitor;
a unit leg configured to change the equivalent capacitance according to a connection with the capacitor;
a control unit configured to control the leg to change the equivalent capacitance; and
an inductor and a compensation voltage source connected in parallel with the leg.

2. The impedance adjustment circuit of claim 1, wherein the unit leg includes:
an adjustment capacitor that has one electrode connected to a reference voltage rail and is equivalently connected to the capacitor to adjust the equivalent capacitance;
a leg voltage source;
two switches connected in series with the leg voltage source;
a first inductor having one electrode connected to a node to which the two switches are connected and the other electrode connected to the other electrode of the adjustment capacitor; and
a diode connected to a radio frequency (RF) rail and having an anode to which an RF voltage is provided and a cathode connected to the other electrode of the first inductor.

3. The impedance adjustment circuit of claim 1, wherein the capacitor has one electrode connected to the RF rail and the other electrode connected to the reference voltage rail.

4. The impedance adjustment circuit of claim 2, wherein a voltage provided by the leg voltage source is greater in magnitude than the RF voltage provided to the RF rail.

5. The impedance adjustment circuit of claim 2, wherein the compensation voltage source compensates for a voltage drop when the switch is turned on and a forward voltage drop of the diode.

6. The impedance adjustment circuit of claim 2, wherein the adjustment capacitor is connected in parallel with the capacitor through the diode, so that the equivalent capacitance is adjusted.

7. The impedance adjustment circuit of claim 6, wherein
the two switches include a first switch connected to the reference voltage rail and a second switch connected to the leg voltage source, and
when the second switch is turned off and the first switch is turned on, the adjustment capacitor and the capacitor are equivalently connected in parallel, so that the equivalent capacitance is adjusted.

8. The impedance adjustment circuit of claim 7, wherein when the first switch is turned off and the second switch is turned on, the connection between the adjustment capacitor and the capacitor is equivalently cut off.

9. The impedance adjustment circuit of claim 2, wherein the unit leg is provided as a plurality of unit legs connected in parallel.

10. The impedance adjustment circuit of claim 9, wherein the adjustment capacitors included in the plurality of unit legs have different capacitances.

11. The impedance adjustment circuit of claim 9, wherein the control unit controls the adjustment capacitor included in one of the plurality of unit legs to be equivalently connected to the capacitor.

12. The impedance adjustment circuit of claim 2, wherein the diode is a P-type-intrinsic-N-type (PIN) diode.

13. An impedance adjustment circuit configured to adjust an impedance by adjusting an equivalent capacitance, the impedance adjustment circuit comprising:
a capacitor;
a unit leg configured to change the equivalent capacitance according to a connection with the capacitor; and
a control unit configured to control the leg to change the equivalent capacitance,
wherein the unit leg includes a diode that has an anode connected to a radio frequency (RF) rail and conducts to change the equivalent capacitance when the control unit controls the leg to increase the equivalent capacitance.

14. The impedance adjustment circuit of claim 13, wherein the unit leg includes:
an adjustment capacitor that has one electrode connected to a reference voltage rail and is equivalently connected to the capacitor to adjust the equivalent capacitance;
a leg voltage source;
two switches connected in series with the leg voltage source; and
a first inductor having one electrode connected to a node to which the two switches are connected and the other electrode connected to the other electrode of the adjustment capacitor,
wherein a cathode of the diode is connected to a node to which the first inductor and the adjustment capacitor are connected, and
the impedance adjustment circuit further includes an inductor and a compensation voltage source that are connected in parallel with the leg.

15. The impedance adjustment circuit of claim 13, wherein the capacitor has one electrode connected to the RF rail and the other electrode connected to a reference voltage rail.

16. The impedance adjustment circuit of claim 14, wherein a voltage provided by the leg voltage source is greater in magnitude than an RF voltage provided to the RF rail.

17. The impedance adjustment circuit of claim 14, wherein the compensation voltage source compensates for a voltage drop when the switch is turned on and a forward voltage drop of the diode.

18. The impedance adjustment circuit of claim 14, wherein the adjustment capacitor is connected in parallel with the capacitor through the diode, so that the equivalent capacitance is adjusted.

19. The impedance adjustment circuit of claim 18, wherein
the two switches include a first switch connected to the reference voltage rail and a second switch connected to the leg voltage source, and
when the second switch is turned off and the first switch is turned on, the adjustment capacitor and the capacitor are equivalently connected in parallel, so that the equivalent capacitance is adjusted.

20. The impedance adjustment circuit of claim 19, wherein when the first switch is turned off and the second switch is turned on, the connection between the adjustment capacitor and the capacitor is equivalently cut off.

21. The impedance adjustment circuit of claim 14, wherein the unit leg is provided as a plurality of unit legs connected in parallel.

22. The impedance adjustment circuit of claim 21, wherein the adjustment capacitors included in the plurality of unit legs have different capacitances.

23. The impedance adjustment circuit of claim 21, wherein the control unit controls the adjustment capacitor included in one of the plurality of unit legs to be equivalently connected to the capacitor.

24. The impedance adjustment circuit of claim 13, wherein the diode is a P-type-intrinsic-N-type (PIN) diode.
